(19) United States
(12) Patent Application Publication
(10) Pub. No.: US 2023/0269867 A1
(43) Pub. Date: Aug. 24, 2023

(54) PCB MLCC-INDUCED ACOUSTIC NOISE REDUCTION

(71) Applicant: Intel Corporation, Santa Clara, CA (US)

(72) Inventors: Smit Kapila, Bangalore (IN); Navneet Singh, BANGALORE (IN); Samantha Rao, Bengaluru (IN); Samarth Alva, Bangalore (IN)

(21) Appl. No.: 17/842,215

(22) Filed: Jun. 16, 2022

Related U.S. Application Data
(60) Provisional application No. 63/311,581, filed on Feb. 18, 2022.

(51) Int. Cl. H05K 1/02; H05K 1/18

(52) U.S. Cl. CPC H05K 1/0271; H05K 1/181; H05K 2201/10015

(57) ABSTRACT

Capacitors are commonly used in design and manufacturing of PCBs, which may exhibit a vibration effect, such as a piezoelectric effect. This vibration may induce acoustic noise. PCB capacitor-induced acoustic noise mitigation may include receiving an AC input that is converted and applied to a voltage rail, which may be used by first capacitor set. An additional capacitor set may receive and invert the voltage rail signal and oscillate (e.g., vibrate) out of phase with the first capacitor set, such that the second capacitor set mitigates or cancels the acoustic noise generated by the first capacitor set.

### PRIORITY

This application claims the benefit fo priority to U.S. Provisional Application Serial No. 63/311,581, filed Feb. 18, 2022, which is incorporated by reference herein in its entirety.

### TECHNICAL FIELD

Embodiments described herein generally relate to printed circuit boards (PCBs).

### BACKGROUND

Capacitors are commonly used in design and manufacturing of PCBs. Various types of capacitors may be used, such as Multilayer Ceramic Capacitors (MLCCs). In operation, MLCCs and other capacitors may exhibit a vibration effect, such as a piezoelectric effect. This vibration may induce acoustic noise, which may become a primary source of system noise, such as in fanless electronic devices. This acoustic noise may be distracting, affect the user’s focus, and affect overall user experience, especially in a silent working environment.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 is a block diagram illustrating PCB capacitor-induced acoustic noise, according to an embodiment.

FIG. 2 is a block diagram illustrating PCB capacitor-induced acoustic noise mitigation, according to an embodiment.

FIG. 3 is a block diagram illustrating a first PCB acoustic noise mitigation capacitor configuration, according to an embodiment.

FIG. 4 is a block diagram illustrating a second PCB acoustic noise mitigation capacitor configuration, according to an embodiment.

FIGS. 5A-5B are pictorial drawings illustrating PCB vibration regions, according to an embodiment.

FIG. 6 is a circuit diagram illustrating PCB acoustic noise mitigation circuits, according to an embodiment.

FIG. 7 is a block diagram illustrating a third PCB acoustic noise mitigation capacitor configuration, according to an embodiment.

FIGS. 8A-8B are pictorial drawings illustrating capacitor vibration arrangements, according to an embodiment.

FIGS. 9A-9B are graphs illustrating capacitor vibration arrangements, according to an embodiment.

FIG. 10 is a flowchart illustrating a method, according to an embodiment.

FIG. 11 is a block diagram of a computing device, according to an embodiment.

### DETAILED DESCRIPTION

In the following description, for purposes of explanation, numerous specific details are set forth to provide a thorough understanding of some example embodiments. It will be evident, however, to one skilled in the art that the present disclosure may be practiced without these specific details.

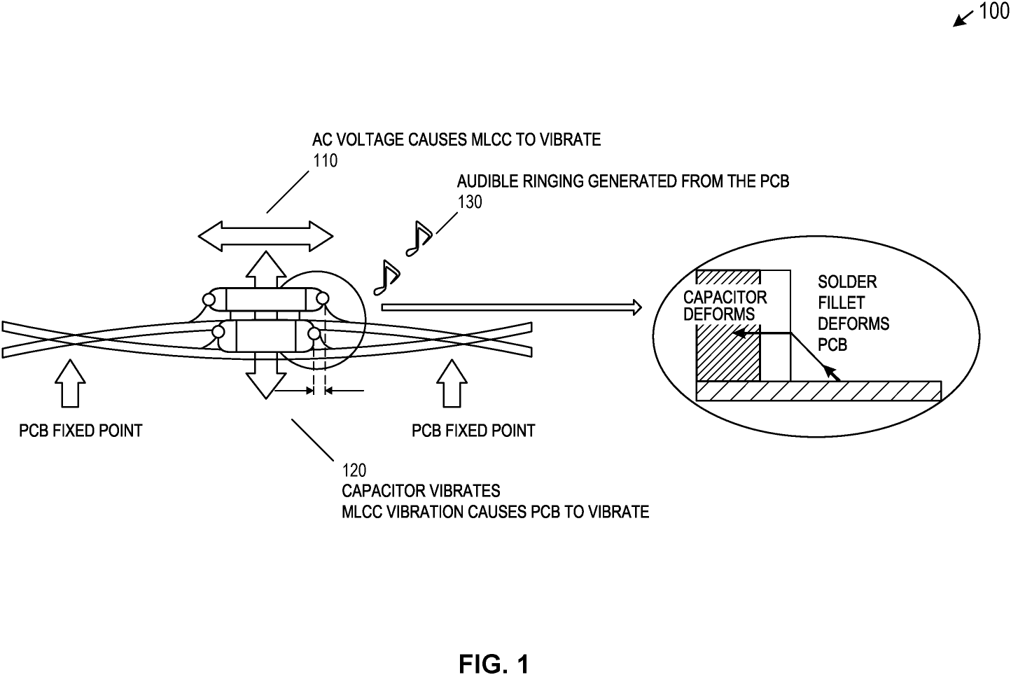

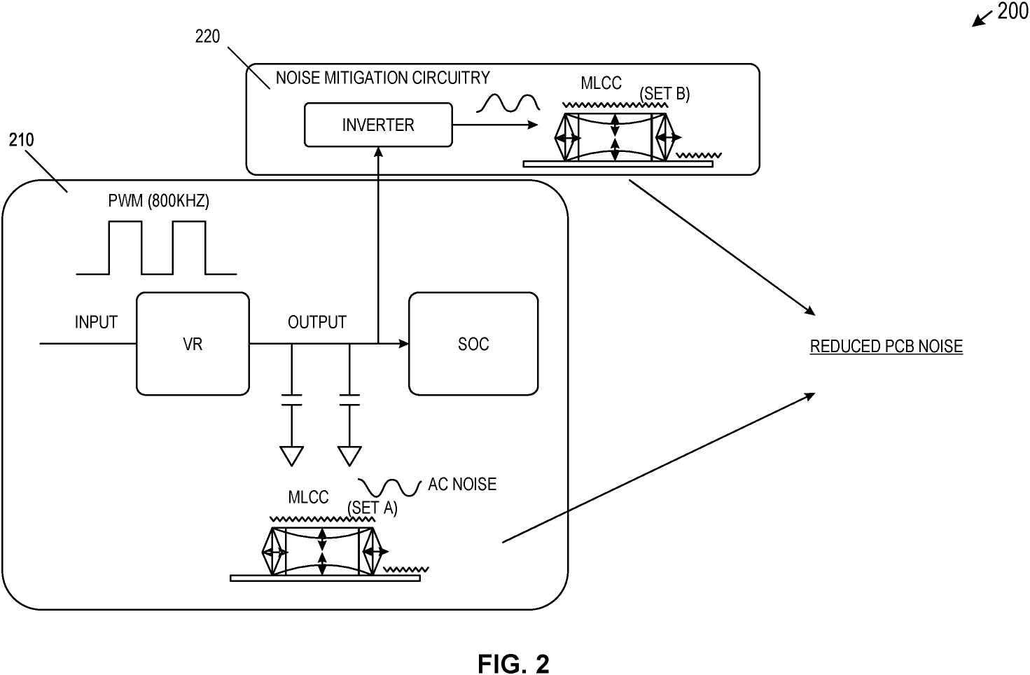

FIG. 1 is a block diagram illustrating PCB capacitor-induced acoustic noise 100, according to an embodiment. Initially, one or more capacitors such as MLCCs on a PCB may vibrate 110 in response to the AC component on the power rails (e.g., system on a chip (SoC) power rails). The capacitor vibration 110 may cause the PCB to vibrate 120 with respect to one or more PCB fixed points, which may generate audible noise (e.g., ringing) 130 from the PCB. However, the same piezoelectric effect that causes the capacitor noise may be used to mitigate or cancel (e.g., reduce or eliminate) the noise source, such as described in FIG. 2

FIG. 2 is a block diagram illustrating PCB capacitor-induced acoustic noise mitigation 200, according to an embodiment. The mitigation 200 may include existing capacitor circuitry 210 and noise mitigation circuitry 220. The existing capacitor circuitry 210 may receive an AC input that is converted and applied to a voltage rail, which may be used by capacitor Set A. Within noise mitigation circuitry 220, additional capacitor Set B may receive and invert the voltage rail signal and oscillate (e.g., vibrate) out of phase with capacitor Set A, such that capacitor Set B mitigates or cancels the acoustic noise generated by capacitor Set A.

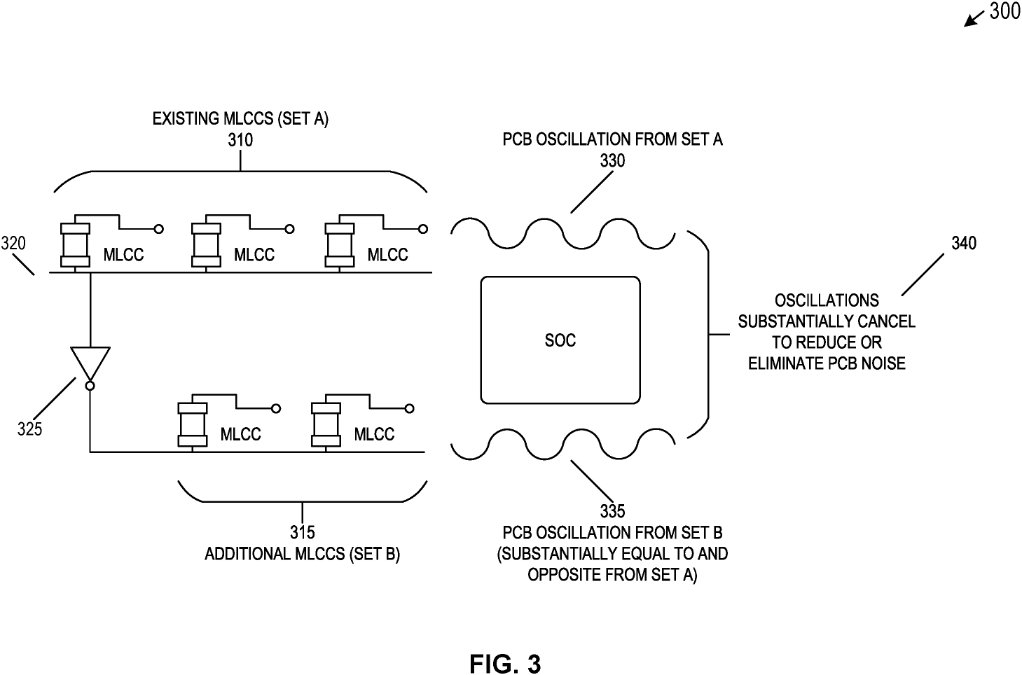

FIG. 3 is a block diagram illustrating a first PCB acoustic noise mitigation capacitor configuration 300, according to an embodiment. Capacitor configuration 300 may include capacitor Set A 310 and capacitor Set B 315. Capacitor Set A 310 may be connected to a signal line 320, and an inverter 325 may be connected to signal line 320 to provide an inverted signal (e.g., out of phase signal) to Set B 315. A signal provided on signal line 320 will cause capacitor Set A 310 to oscillate at a first frequency and amplitude 330, and the inverted signal will cause Set B 315 to oscillate at a second frequency at amplitude 335, where the first frequency and amplitude 330 are substantially equal to and opposite from the second frequency at amplitude 335. This vibration from capacitor Set B 315 will be out of phase with the vibration from capacitor Set A 310, and the two vibration signals will reduce or minimize the overall PCB vibration and reduce or minimize the resultant PCB noise 340. Mitigation circuitry 220 may be designed to reduce or minimize voltage rail signal latency such that capacitor Set B 315 may oscillate in a substantially opposite phase (e.g., 180°, π/2) from capacitor Set A 310. This may include selecting a low-latency inverter 325, and selecting a capacitor and inverter PCB layout to reduce or minimize latency.

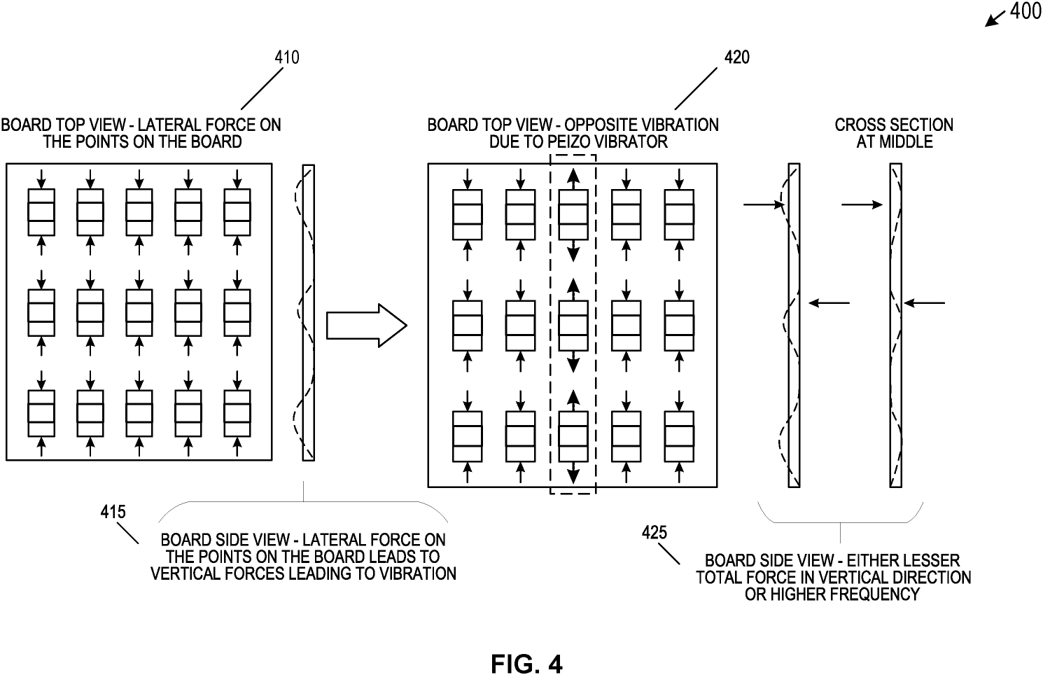

FIG. 4 is a block diagram illustrating a second PCB acoustic noise mitigation capacitor configuration 400, according to an embodiment. The second capacitor configuration 400 shows a first PCB top view 410 that includes an array of capacitors operating based on a common voltage rail signal, such as capacitor Set A. As shown in the board side view 415, the lateral force on the points on the board results in vertical forces that lead to vibration, which generates unwanted acoustic noise. The second capacitor configuration 400 also shows a second PCB top view 420 that includes an array of capacitors operating based on a common voltage rail signal, and includes a vertical row of capacitors operating based on an inverted common voltage rail signal, such as capacitor Set B. As shown in the board side view 425, the lateral force on the points on the board from both groups of capacitors may reduce or cancel the vertical forces that lead to vibration, which reduces or cancels unwanted acoustic noise.

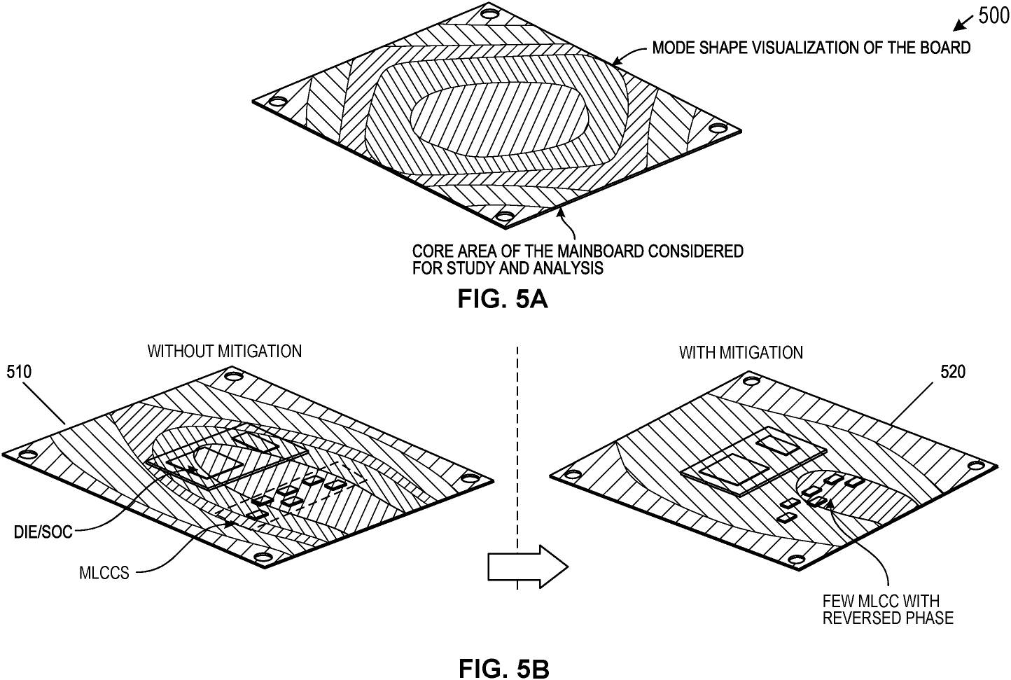

As shown in second PCB top view 420, the number and location of the mitigation capacitors (e.g., capacitor Set B) may be selected to offset the non-inverted capacitors (e.g., capacitor Set A). In an example, there may be fewer mitigation capacitors than non-inverted capacitors, and the mitigation capacitors may use an amplified inverted signal to offset the non-inverted capacitors. In an example, mitigation capacitors may be located on a reverse side of a PCB and driven by a non-inverted signal. However, for a PCB where all components are on the same side of a PCB (e.g., smartwatches, portable electronic devices, and any other PCB that requires a low z-height), the mitigation capacitors are driven by an in verted signal and located on the same side as the non-inverted capacitors, such as shown in FIG. 4. In an example, the mitigation capacitors may be placed in the center of a PCB, which may generate a greater vibration than non-inverted capacitors that are placed closer to the PCB edges, PCB corners, or other PCB attachment points, such as shown in FIGS. 5A-5B.

FIGS. 5A-5B are pictorial drawings illustrating PCB vibration regions 500, according to an embodiment. As shown in FIG. 5A, the vibration regions may be lowest closest to the four corner attachment points, and the vibration regions may increase in magnitude to a maximum vibration region in the center of the PCB. FIG. 5B shows a PCB without capacitor vibration mitigation 510, which shows five vibration regions, with the highest intensity vibration in the center region that includes the die or SoC and the MLCCs or other capacitors. FIG. 5B also shows a PCB with capacitor vibration mitigation 520, which shows that vibration is reduced to the three vibration regions of lowest intensity, demonstrating the reduction in vibration provided by the capacitor vibration mitigation.

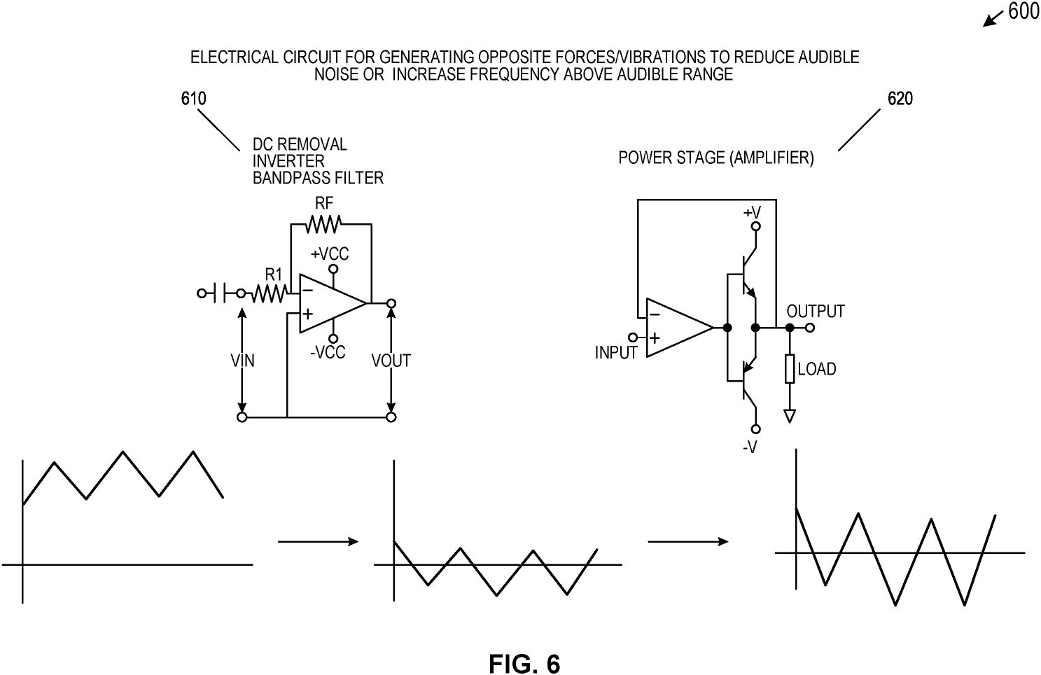

FIG. 6 is a circuit diagram illustrating PCB acoustic noise mitigation circuits 600, according to an embodiment. The PCB acoustic noise mitigation circuits 600 may include an inverter circuit 610, where inverter circuit 610 may include a DC removal component and bandpass filter. The inverter circuit 610 may shift a voltage waveform down to be approximately centered around 0 VDC using a DC block capacitor to filter out DC component of voltage (e.g., allowing AC to pass through), and invert the DC-shifted voltage waveform. The DC block capacitor may include an MLCC, and may use a bandpass filter to filter out higher frequency signals. The PCB acoustic noise mitigation circuits 600 may include an amplifier circuit 620, which may receive and amplify the waveform from the inverter circuit 610. The amplifier circuit 620 may be used to provide a waveform such that the equivalent inverse piezo effect is achieved by a smaller quantity and smaller package of acoustic noise mitigation capacitors. The PCB acoustic noise mitigation circuits 600 and corresponding acoustic noise mitigation capacitors may be selected to reduce or minimize the PCB footprint, and to reduce or minimize the effect on system design or system functionality. The power requirements for PCB acoustic noise mitigation circuits 600 and corresponding acoustic noise mitigation capacitors may be reduced further by only using these components during voltage transients, such as during voltage identification (VID) transient events.

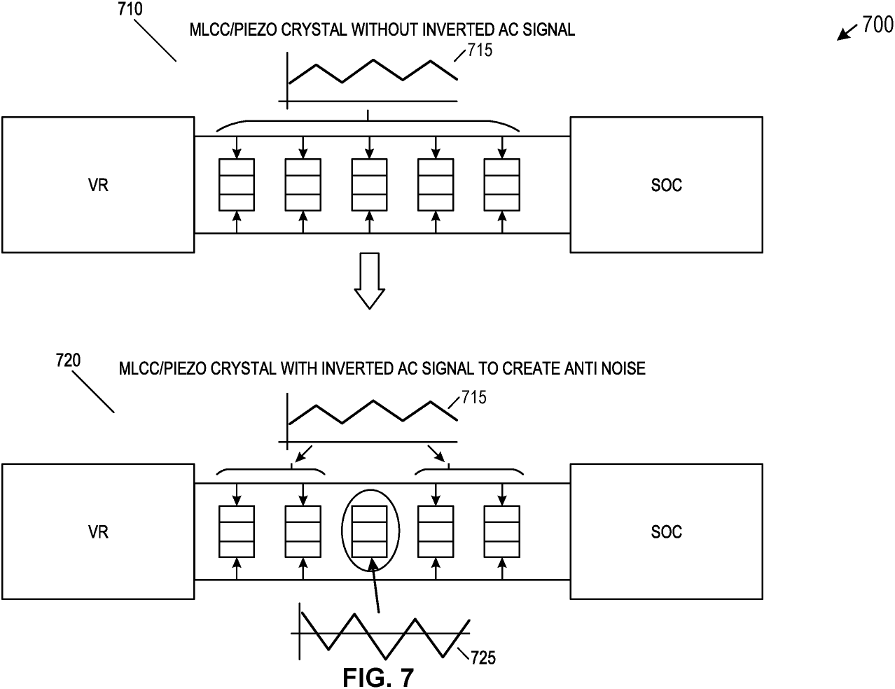

FIG. 7 is a block diagram illustrating a third PCB acoustic noise mitigation capacitor configuration 700, according to an embodiment. The capacitor configuration 700 shows the application of the inverted and amplified signal, such as an inverted and amplified signal generated by PCB acoustic noise mitigation circuits 600. A first configuration 710 shows all capacitors being driven by the non-inverted signal 715, which may generate unwanted acoustic noise. A second configuration 720 shows the outside four capacitors being driven by the non-inverted signal 715, and a central capacitor being driven by an inverted and amplified signal 725. One or more noise mitigation capacitors may be positioned to increase or maximize the effect of that capacitor’s vibration, such as being positioned in the center of a PCB (e.g., between one or more PCB mount points). In an example, a point-of-load analysis may be used to analyze a PCB to identify a central load region or location of a PCB, which may be based on a PCB flexibly, a number and location of rigid mount points, and other PCB features. One or more piezoelectric elements or other vibration-inducing elements may be used in addition to or as an alternative to noise mitigation capacitors, which may be used to generate an opposite phase vibration to reduce or minimize unwanted acoustic noise.

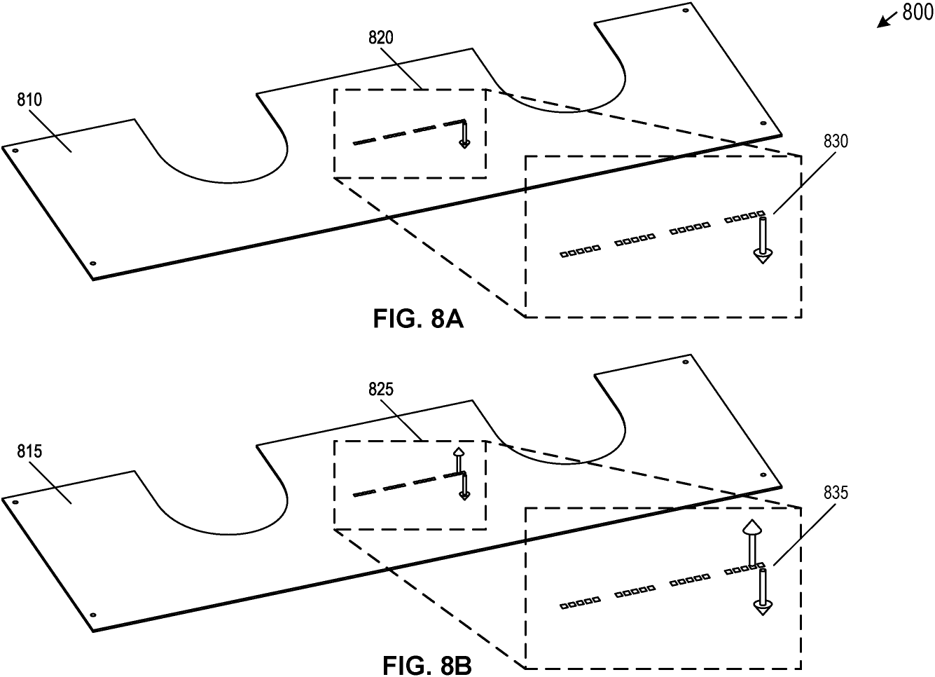

FIGS. 8A-8B are pictorial drawings illustrating capacitor vibration arrangements 800, according to an embodiment. FIG. 8A shows a first example PCB 810 that includes a first example region 820 of oscillating capacitors. The first example region 820 shows a force vector 830 generated by one of the capacitors. While force vector 830 is shown in a single direction, this force vector 830 represents the magnitude of an oscillating signal oscillating with a first phase.

Similar to FIG. 8A, FIG. 8B shows a second example PCB 815 that includes a second example region 825 of oscillating capacitors. The second example region 825 shows equal and opposite force vectors 835 generated by adjacent capacitors. While force vectors 835 are each shown in a single direction, force vectors 835 represents the magnitude of an oscillating signal oscillating with a first phase and the equal and opposite magnitude of an acoustic-cancelling oscillating signal that oscillates substantially out of phase with the first oscillating signal. The equal and opposite force vectors 835 substantially cancel each other out, thereby reducing or eliminating audible acoustic noise caused by the vibration.

While equal and opposite force vectors 835 are shown and described as being equal in magnitude, in various embodiments the force vectors 835 may be substantially equal such that the opposing forces may reduce or eliminate audible acoustic noise caused by any PCB vibration. Similarly, the directions of the force vectors 835 may be substantially opposite in direction sufficient to reduce or eliminate audible acoustic noise caused by PCB vibration, and the phase of the out-of-phase capacitors may be substantially equal to (e.g., 180°, π/2) sufficient to reduce or eliminate audible acoustic noise caused by PCB vibration.

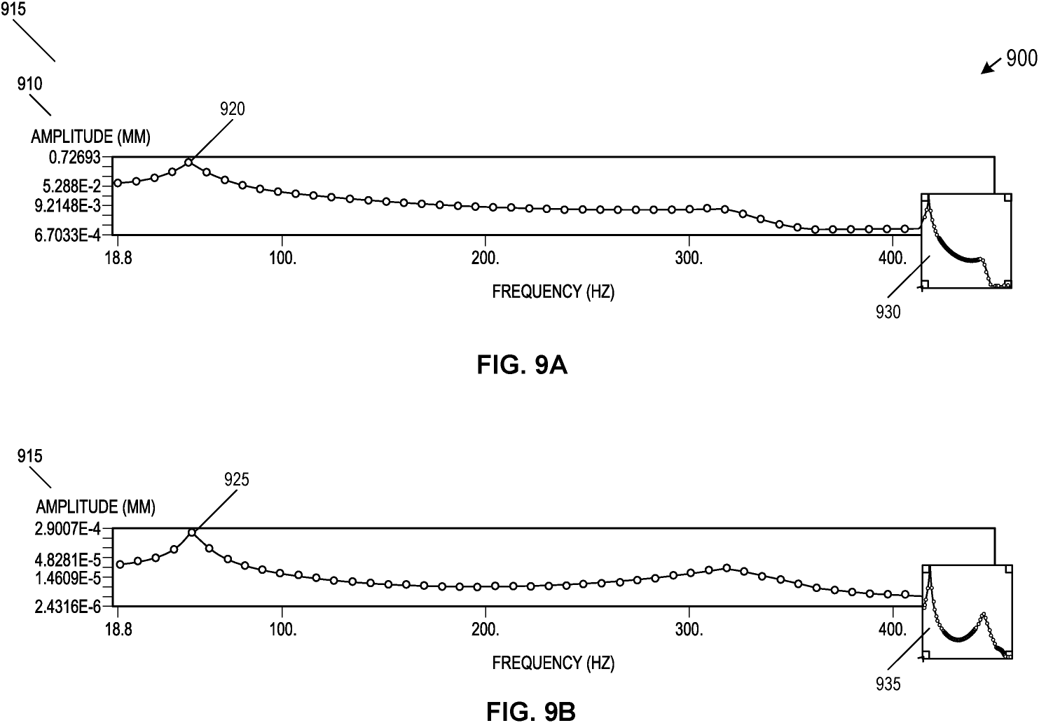

FIGS. 9A-9B are graphs illustrating capacitor vibration arrangements 900, according to an embodiment. FIG. 9A shows a first example displacement graph 910 that may correspond to a first set of oscillating capacitors, such as the first example region 820 of oscillating capacitors shown in FIG. 8A. As shown in first example displacement graph 910, the peak displacement 920 of the PCB may correspond to approximately 0.72 mm displacement at 54 Hz. The displacement values decrease for the frequencies above the maximum displacement, but remain above 0.00067 mm displacement. A horizontally compressed copy 930 of the first example displacement graph 910 also shows a subsequent peak that is similar in magnitude to the preceding values.

Similar to FIG. 9A, FIG. 9B shows a second example displacement graph 915 that may correspond to a second set of oscillating capacitors, such as the second example region 825 of oscillating capacitors shown in FIG. 8B. As shown in second example displacement graph 915, the peak displacement 925 of the PCB may correspond to approximately 0.00029 mm displacement at 54 Hz. This peak value of 0.00029 mm displacement in this second example displacement graph 915 is lower than the minimum value 0.00067 mm displacement in the first example displacement graph 910. A horizontally compressed copy 935 of the first example displacement graph 915 shows a subsequent peak that is greater than preceding values. The frequency at which the peak amplitude and any subsequent peaks occur may be based on the resonant frequency of the PCB. However, regardless of peak frequency values, the maximum amplitude of the displacement values within the second example displacement graph 915 are lower than any of the values in the first example displacement graph 910. This demonstrates the improvement provided by the use of multiple vibrating capacitors with equal and opposite magnitudes in reducing or eliminating audible acoustic noise caused by the vibration.

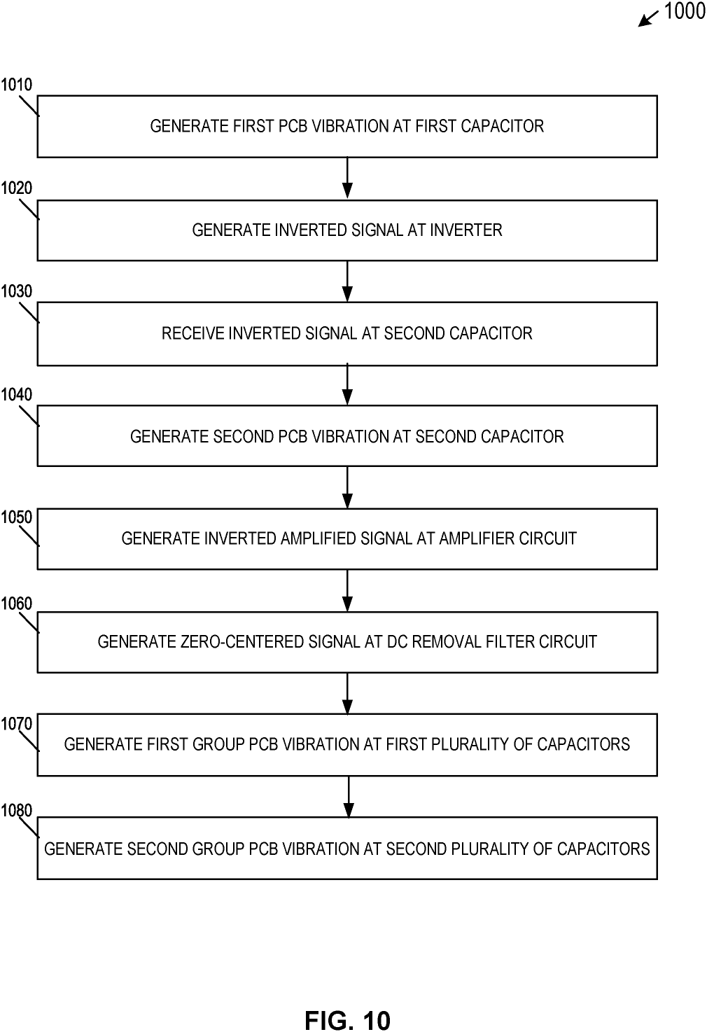

FIG. 10 is a flowchart illustrating a method 1000 for reducing printed circuit board vibration, according to an embodiment. Method 1000 includes generating 1010 a first PCB vibration with an associated first vibration phase at a first capacitor, the first capacitor to receive a first signal and disposed on a first side of a printed circuit board (PCB). Method 1000 includes generating 1020 an inverted signal at an inverter based on the first signal. Method 1000 includes receiving 1030 the inverted signal at a second capacitor coupled to the inverter. Method 1000 includes generating 1040 a second PCB vibration at the second capacitor. The second PCB vibration may have an associated second vibration phase opposite the first PCB vibration phase, where the second PCB vibration opposes the first PCB vibration to reduce an overall PCB vibration.

A first magnitude associated with the first PCB vibration may be substantially equal to and opposite from a second magnitude associated with the second PCB vibration. The first PCB vibration may cause the PCB to generate a first acoustic noise. The second PCB vibration opposes the first PCB vibration to reduce the first acoustic noise. The PCB may include a rigid PCB attachment point. The second capacitor may be arranged on the PCB relative to the rigid PCB attachment point to reduce the first PCB vibration.

Method 1000 may include generating 1050 an inverted amplified signal at an amplifier circuit coupled to the inverter and the second plurality of capacitors. The second plurality of capacitors may generate the second group PCB vibration based on the inverted amplified signal. The amplifier circuit may be configured to cause the second group PCB vibration to be substantially equal to and opposite from the first group PCB vibration to reduce the first group PCB vibration.

Method 1000 may include generating 1060 a zero-centered signal at a direct current (DC) removal filter circuit by shifting the first signal to be substantially centered around zero volts DC. The inverter may generate the inverted signal based on the zero-centered signal. The first capacitor and the second capacitor may include multilayer ceramic capacitors. The first capacitor and the second capacitor may include piezoelectric elements.

Method 1000 may include generating 1070 a first group PCB vibration at a first plurality of capacitors coupled to the first signal and disposed on the first side of the PCB. The first plurality of capacitors may include the first capacitor, the first group PCB vibration associated with the first vibration phase. Method 1000 may include generating 1080 a second group PCB vibration at a second plurality of capacitors coupled to the second signal and disposed on the first side of the PCB. The second plurality of capacitors may include fewer capacitors than the first plurality of capacitors. The second plurality of capacitors may include the second capacitor, the second group PCB vibration associated with the second vibration phase to reduce the first group PCB vibration. The second plurality of capacitors may be arranged on the PCB relative to the rigid PCB attachment point such that the second group PCB vibration is substantially equal to and opposite from the first group PCB vibration to reduce the first group PCB vibration.

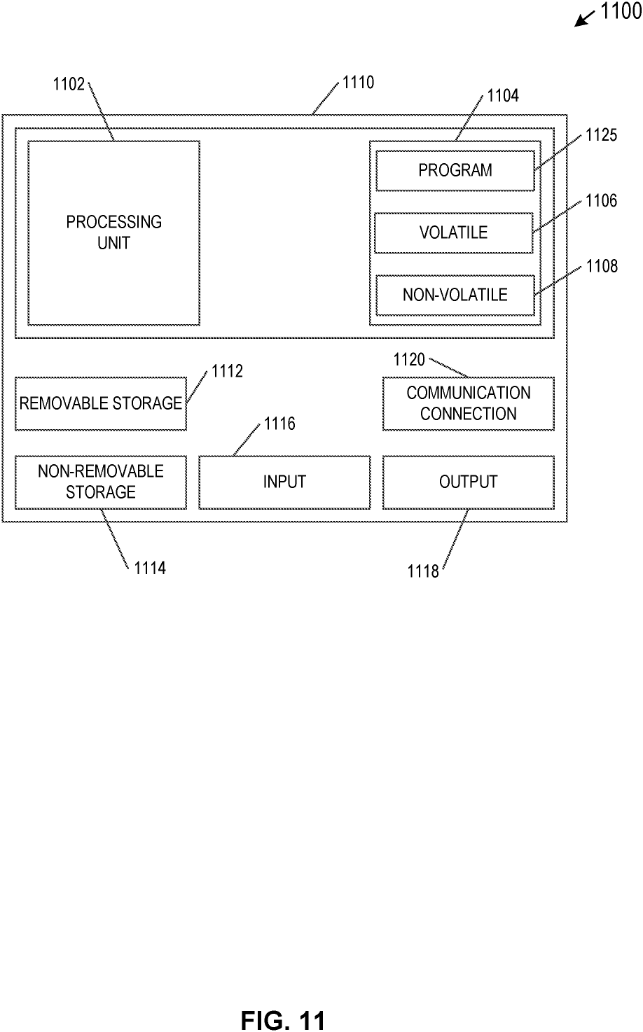

FIG. 11 is a block diagram of a computing device 1100, according to an embodiment. The performance of one or more components within computing device 1100 may be improved by including one or more of the circuits or circuitry methods described herein. Computing device 1100 may include a first stacked transistor voltage converter circuit, a first stacked transistor driver circuit coupled to the first stacked transistor voltage converter circuit, a second stacked transistor voltage converter circuit coupled to the first stacked transistor voltage converter circuit, and a second stacked transistor driver circuit coupled to the second stacked transistor voltage converter circuit.

In one embodiment, multiple such computer systems are used in a distributed network to implement multiple components in a transaction-based environment. An object-oriented, service-oriented, or other architecture may be used to implement such functions and communicate between the multiple systems and components. In some embodiments, the computing device of FIG. 11 is an example of a client device that may invoke methods described herein over a network. In some embodiments, the computing device of FIG. 11 is an example of one or more of the personal computer, smartphone, tablet, or various servers.

One example computing device in the form of a computer 1110, may include a processing unit 1102, memory 1104, removable storage 1112, and non-removable storage 1114. Although the example computing device is illustrated and described as computer 1110, the computing device may be in different forms in different embodiments. For example, the computing device may instead be a smartphone, a tablet, or other computing device including the same or similar elements as illustrated and described with regard to FIG. 11. Further, although the various data storage elements are illustrated as part of the computer 1110, the storage may include cloud-based storage accessible via a network, such as the Internet.

Returning to the computer 1110, memory 1104 may include volatile memory 1106 and non-volatile memory 1108. Computer 1110 may include or have access to a computing environment that includes a variety of computer-readable media, such as volatile memory 1106 and non-volatile memory 1108, removable storage 1112 and non-removable storage 1114. Computer storage includes random access memory (RAM), read only memory (ROM), erasable programmable read-only memory (EPROM) & electrically erasable programmable read-only memory (EEPROM), flash memory or other memory technologies, compact disc read-only memory (CD ROM), Digital Versatile Disks (DVD) or other optical disk storage, magnetic cassettes, magnetic tape, magnetic disk storage or other magnetic storage devices, or any other medium capable of storing computer-readable instructions. Computer 1110 may include or have access to a computing environment that includes input 1116, output 1118, and a communication connection 1120. The input 1116 may include one or more of a touchscreen, touchpad, mouse, keyboard, camera, and other input devices. The input 1116 may include a navigation sensor input, such as a GNSS receiver, a SOP receiver, an inertial sensor (e.g., accelerometers, gyroscopes), a local ranging sensor (e.g., LIDAR), an optical sensor (e.g., cameras), or other sensors. The computer may operate in a networked environment using a communication connection 1120 to connect to one or more remote computers, such as database servers, web servers, and another computing device. An example remote computer may include a personal computer (PC), server, router, network PC, a peer device or other common network node, or the like. The communication connection 1120 may be a network interface device such as one or both of an Ethernet card and a wireless card or circuit that may be connected to a network. The network may include one or more of a Local Area Network (LAN), a Wide Area Network (WAN), the Internet, and other networks.

Computer-readable instructions stored on a computer-readable medium are executable by the processing unit 1102 of the computer 1110. A hard drive (magnetic disk or solid state), CD-ROM, and RAM are some examples of articles including a non-transitory computer-readable medium. For example, various computer programs 1125 or apps, such as one or more applications and modules implementing one or more of the methods illustrated and described herein or an app or application that executes on a mobile device or is accessible via a web browser, may be stored on a non-transitory computer-readable medium.

The apparatuses and methods described above may include or be included in high-speed computers, communication and signal processing circuitry, single-processor module or multi-processor modules, single embedded processors or multiple embedded processors, multi-core processors, message information switches, and application-specific modules including multilayer or multi-chip modules. Such apparatuses may further be included as subcomponents within a variety of other apparatuses (e.g., electronic systems), such as televisions, cellular telephones, personal computers (e.g., laptop computers, desktop computers, handheld computers, etc.), tablets (e.g., tablet computers), workstations, radios, video players, audio players (e.g., MP3 (Motion Picture Experts Group, Audio Layer 3) players), vehicles, medical devices (e.g., heart monitors, blood pressure monitors, etc.), set top boxes, and others.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, a list of items joined by the term “at least one of” may mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A may include a single element or multiple elements. Item B may include a single element or multiple elements. Item C may include a single element or multiple elements.

In the detailed description and the claims, a list of items joined by the term “one of” may mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A may include a single element or multiple elements. Item B may include a single element or multiple elements. Item C may include a single element or multiple elements.

### ADDITIONAL NOTES AND EXAMPLES

Example 1 is a system comprising: a first capacitor to receive a first signal and disposed on a first side of a printed circuit board (PCB), the first capacitor to generate a first PCB vibration associated with a first vibration phase; an inverter to generate an inverted signal based on the first signal; and a second capacitor coupled to the inverter to receive the inverted signal and to generate a second PCB vibration associated with a second vibration phase opposite the first vibration phase, the second PCB vibration opposing the first PCB vibration to reduce an overall PCB vibration.

In Example 2, the subject matter of Example 1 includes, wherein a first magnitude associated with the first PCB vibration is substantially equal to and opposite from a second magnitude associated with the second PCB vibration.

In Example 3, the subject matter of Examples 1-2 includes, wherein: the first PCB vibration causes the PCB to generate a first audible vibration; and the second PCB vibration opposes the first PCB vibration to reduce the first audible vibration.

In Example 4, the subject matter of Examples 1-3 includes, wherein: the PCB includes a rigid PCB attachment point; and the second capacitor is arranged on the PCB with respect to the rigid PCB attachment point to reduce the first PCB vibration.

In Example 5, the subject matter of Example 4 includes, a first plurality of capacitors coupled to the first signal and disposed on the first side of the PCB, the first plurality of capacitors including the first capacitor, the first plurality of capacitors to generate a first group PCB vibration associated with the first vibration phase; and a second plurality of capacitors coupled to the inverted signal and disposed on the first side of the PCB, the second plurality of capacitors including fewer capacitors than the first plurality of capacitors, the second plurality of capacitors including the second capacitor, the second plurality of capacitors to generate a second group PCB vibration associated with the second vibration phase to reduce the first group PCB vibration.

In Example 6, the subject matter of Example 5 includes, wherein the second plurality of capacitors is arranged on the PCB with respect to the rigid PCB attachment point such that the second group PCB vibration is substantially equal to and opposite from the first group PCB vibration to reduce the first group PCB vibration.

In Example 7, the subject matter of Examples 5-6 includes, an amplifier circuit coupled to the inverter and the second plurality of capacitors to generate an inverted amplified signal, wherein: the second plurality of capacitors generate the second group PCB vibration based on the inverted amplified signal; and the amplifier circuit is configured to cause the second group PCB vibration to be substantially equal to and opposite from the first group PCB vibration to reduce the first group PCB vibration.

In Example 8, the subject matter of Examples 1-7 includes, a direct current (DC) removal filter circuit to generate a zero-centered signal by shifting the first signal to be substantially centered around zero volts DC; wherein the inverter generates the inverted signal based on the zero-centered signal.

In Example 9, the subject matter of Examples 1-8 includes, wherein the first capacitor and the second capacitor include multilayer ceramic capacitors.

In Example 10, the subject matter of Examples 1-9 includes, wherein the first capacitor and the second capacitor include piezoelectric elements.

Example 11 is a method for reducing printed circuit board vibration, the method comprising: generating a first PCB vibration associated with a first vibration phase at a first capacitor, the first capacitor to receive a first signal and disposed on a first side of a printed circuit board (PCB); generating an inverted signal at an inverter based on the first signal; receiving the inverted signal at a second capacitor coupled to the inverter; and generating a second PCB vibration at the second capacitor, the second PCB vibration associated with a second vibration phase opposite the first vibration phase, the second PCB vibration opposing the first PCB vibration to reduce an overall PCB vibration.

In Example 12, the subject matter of Example 11 includes, wherein a first magnitude associated with the first PCB vibration is substantially equal to and opposite from a second magnitude associated with the second PCB vibration.

In Example 13, the subject matter of Examples 11-12 includes, wherein: the first PCB vibration causes the PCB to generate a first acoustic noise; and the second PCB vibration opposes the first PCB vibration to reduce the first acoustic noise.

In Example 14, the subject matter of Examples 11-13 includes, wherein: the PCB includes a rigid PCB attachment point; and the second capacitor is arranged on the PCB with respect to the rigid PCB attachment point to reduce the first PCB vibration.

In Example 15, the subject matter of Example 14 includes, generating a first group PCB vibration at a first plurality of capacitors coupled to the first signal and disposed on the first side of the PCB, the first plurality of capacitors including the first capacitor, the first group PCB vibration associated with the first vibration phase; and generating a second group PCB vibration at a second plurality of capacitors coupled to the inverted signal and disposed on the first side of the PCB, the second plurality of capacitors including fewer capacitors than the first plurality of capacitors, the second plurality of capacitors including the second capacitor, the second group PCB vibration associated with the second vibration phase to reduce the first group PCB vibration.

In Example 16, the subject matter of Example 15 includes, wherein the second plurality of capacitors is arranged on the PCB with respect to the rigid PCB attachment point such that the second group PCB vibration is substantially equal to and opposite from the first group PCB vibration to reduce the first group PCB vibration.

In Example 17, the subject matter of Examples 15-16 includes, generating an inverted amplified signal at an amplifier circuit coupled to the inverter and the second plurality of capacitors, wherein: the second plurality of capacitors generate the second group PCB vibration based on the inverted amplified signal; and the amplifier circuit is configured to cause the second group PCB vibration to be substantially equal to and opposite from the first group PCB vibration to reduce the first group PCB vibration.

In Example 18, the subject matter of Examples 11-17 includes, generating a zero-centered signal at a direct current (DC) removal filter circuit by shifting the first signal to be substantially centered around zero volts DC, wherein the inverter generates the inverted signal based on the zero-centered signal.

In Example 19, the subject matter of Examples 11-18 includes, wherein the first capacitor and the second capacitor include multilayer ceramic capacitors.

In Example 20, the subject matter of Examples 11-19 includes, wherein the first capacitor and the second capacitor include piezoelectric elements.

Example 21 is at least one non-transitory machine-readable storage medium, comprising a plurality of instructions that, responsive to being executed with processor circuitry of a computer-controlled device, cause the processor circuitry to: generate a first PCB vibration associated with a first vibration phase at a first capacitor, the first capacitor to receive a first signal and disposed on a first side of a printed circuit board (PCB); generate an inverted signal at an inverter based on the first signal; receive the inverted signal at a second capacitor coupled to the inverter; and generate a second PCB vibration at the second capacitor, the second PCB vibration associated with a second vibration phase opposite the first vibration phase, the second PCB vibration opposing the first PCB vibration to reduce an overall PCB vibration.

In Example 22, the subject matter of Example 21 includes, wherein a first magnitude associated with the first PCB vibration is substantially equal to and opposite from a second magnitude associated with the second PCB vibration.

In Example 23, the subject matter of Examples 21-22 includes, wherein: the first PCB vibration causes the PCB to generate a first acoustic noise; and the second PCB vibration opposes the first PCB vibration to reduce the first acoustic noise.

In Example 24, the subject matter of Examples 21-23 includes, wherein: the PCB includes a rigid PCB attachment point; and the second capacitor is arranged on the PCB with respect to the rigid PCB attachment point to reduce the first PCB vibration.

In Example 25, the subject matter of Example 24 includes, the plurality of instructions further causing the processor circuitry to: generate a first group PCB vibration at a first plurality of capacitors coupled to the first signal and disposed on the first side of the PCB, the first plurality of capacitors including the first capacitor, the first group PCB vibration associated with the first vibration phase; and generate a second group PCB vibration at a second plurality of capacitors coupled to the inverted signal and disposed on the first side of the PCB, the second plurality of capacitors including fewer capacitors than the first plurality of capacitors, the second plurality of capacitors including the second capacitor, the second group PCB vibration associated with the second vibration phase to reduce the first group PCB vibration.

In Example 26, the subject matter of Example 25 includes, wherein the second plurality of capacitors is arranged on the PCB with respect to the rigid PCB attachment point such that the second group PCB vibration is substantially equal to and opposite from the first group PCB vibration to reduce the first group PCB vibration.

In Example 27, the subject matter of Examples 25-26 includes, the plurality of instructions further causing the processor circuitry to generate an inverted amplified signal at an amplifier circuit coupled to the inverter and the second plurality of capacitors, wherein: the second plurality of capacitors generate the second group PCB vibration based on the inverted amplified signal; and the amplifier circuit is configured to cause the second group PCB vibration to be substantially equal to and opposite from the first group PCB vibration to reduce the first group PCB vibration.

In Example 28, the subject matter of Examples 21-27 includes, the plurality of instructions further causing the processor circuitry to generate a zero-centered signal at a direct current (DC) removal filter circuit by shifting the first signal to be substantially centered around zero volts DC, wherein the inverter generates the inverted signal based on the zero-centered signal.

In Example 29, the subject matter of Examples 21-28 includes, wherein the first capacitor and the second capacitor include multilayer ceramic capacitors.

In Example 30, the subject matter of Examples 21-29 includes, wherein the first capacitor and the second capacitor include piezoelectric elements.

Example 31 is at least one machine-readable medium including instructions that, when executed by processing circuitry, cause the processing circuitry to perform operations to implement of any of Examples 1-30.

Example 32 is an apparatus comprising means to implement of any of Examples 1-30.

Example 33 is a system to implement of any of Examples 1-30.

Example 34 is a method to implement of any of Examples 1-30.

The subject matter of any Examples above may be combined in any combination.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. A system comprising:
a first capacitor to receive a first signal and disposed on a first side of a printed circuit board (PCB), the first capacitor to generate a first PCB vibration associated with a first vibration phase;
an inverter to generate an inverted signal based on the first signal; and
a second capacitor coupled to the inverter to receive the inverted signal and to generate a second PCB vibration associated with a second vibration phase opposite the first vibration phase, the second PCB vibration opposing the first PCB vibration to reduce an overall PCB vibration.

2. The system of claim 1, wherein a first magnitude associated with the first PCB vibration is substantially equal to and opposite from a second magnitude associated with the second PCB vibration.

3. The system of claim 1, wherein:
the first PCB vibration causes the PCB to generate a first audible vibration; and
the second PCB vibration opposes the first PCB vibration to reduce the first audible vibration.

4. The system of claim 1, wherein:
the PCB includes a rigid PCB attachment point; and
the second capacitor is arranged on the PCB with respect to the rigid PCB attachment point to reduce the first PCB vibration.

5. The system of claim 4, further including:
a first plurality of capacitors coupled to the first signal and disposed on the first side of the PCB, the first plurality of capacitors including the first capacitor, the first plurality of capacitors to generate a first group PCB vibration associated with the first vibration phase; and
a second plurality of capacitors coupled to the inverted signal and disposed on the first side of the PCB, the second plurality of capacitors including fewer capacitors than the first plurality of capacitors, the second plurality of capacitors including the second capacitor, the second plurality of capacitors to generate a second group PCB vibration associated with the second vibration phase to reduce the first group PCB vibration.

6. The system of claim 5, wherein the second plurality of capacitors is arranged on the PCB with respect to the rigid PCB attachment point such that the second group PCB vibration is substantially equal to and opposite from the first group PCB vibration to reduce the first group PCB vibration.

7. The system of claim 5, further including an amplifier circuit coupled to the inverter and the second plurality of capacitors to generate an inverted amplified signal, wherein:
the second plurality of capacitors generate the second group PCB vibration based on the inverted amplified signal; and
the amplifier circuit is configured to cause the second group PCB vibration to be substantially equal to and opposite from the first group PCB vibration to reduce the first group PCB vibration.

8. The system of claim 1, further including a direct current (DC) removal filter circuit to generate a zero-centered signal by shifting the first signal to be substantially centered around zero volts DC;
wherein the inverter generates the inverted signal based on the zero-centered signal.

9. The system of claim 1, wherein the first capacitor and the second capacitor include multilayer ceramic capacitors.

10. The system of claim 1, wherein the first capacitor and the second capacitor include piezoelectric elements.

11. A method for reducing printed circuit board vibration, the method comprising:
generating a first PCB vibration associated with a first vibration phase at a first capacitor, the first capacitor to receive a first signal and disposed on a first side of a printed circuit board (PCB);
generating an inverted signal at an inverter based on the first signal;
receiving the inverted signal at a second capacitor coupled to the inverter; and
generating a second PCB vibration at the second capacitor, the second PCB vibration associated with a second vibration phase opposite the first vibration phase, the second PCB vibration opposing the first PCB vibration to reduce an overall PCB vibration.

12. The method of claim 11, wherein a first magnitude associated with the first PCB vibration is substantially equal to and opposite from a second magnitude associated with the second PCB vibration.

13. The method of claim 11, wherein:
the first PCB vibration causes the PCB to generate a first acoustic noise; and
the second PCB vibration opposes the first PCB vibration to reduce the first acoustic noise.

14. The method of claim 11, wherein:
the PCB includes a rigid PCB attachment point; and
the second capacitor is arranged on the PCB with respect to the rigid PCB attachment point to reduce the first PCB vibration.

15. The method of claim 14, further including:
generating a first group PCB vibration at a first plurality of capacitors coupled to the first signal and disposed on the first side of the PCB, the first plurality of capacitors including the first capacitor, the first group PCB vibration associated with the first vibration phase; and
generating a second group PCB vibration at a second plurality of capacitors coupled to the inverted signal and disposed on the first side of the PCB, the second plurality of capacitors including fewer capacitors than the first plurality of capacitors, the second plurality of capacitors including the second capacitor, the second group PCB vibration associated with the second vibration phase to reduce the first group PCB vibration.

16. The method of claim 15, wherein the second plurality of capacitors is arranged on the PCB with respect to the rigid PCB attachment point such that the second group PCB vibration is substantially equal to and opposite from the first group PCB vibration to reduce the first group PCB vibration.

17. The method of claim 15, further including generating an inverted amplified signal at an amplifier circuit coupled to the inverter and the second plurality of capacitors, wherein:
the second plurality of capacitors generate the second group PCB vibration based on the inverted amplified signal; and
the amplifier circuit is configured to cause the second group PCB vibration to be substantially equal to and opposite from the first group PCB vibration to reduce the first group PCB vibration.

18. The method of claim 11, further including generating a zero-centered signal at a direct current (DC) removal filter circuit by shifting the first signal to be substantially centered around zero volts DC, wherein the inverter generates the inverted signal based on the zero-centered signal.

19. At least one non-transitory machine-readable storage medium, comprising a plurality of instructions that, responsive to being executed with processor circuitry of a computer-controlled device, cause the processor circuitry to:
generate a first PCB vibration associated with a first vibration phase at a first capacitor, the first capacitor to receive a first signal and disposed on a first side of a printed circuit board (PCB);
generate an inverted signal at an inverter based on the first signal;
receive the inverted signal at a second capacitor coupled to the inverter; and
generate a second PCB vibration at the second capacitor, the second PCB vibration associated with a second vibration phase opposite the first vibration phase, the second PCB vibration opposing the first PCB vibration to reduce an overall PCB vibration.

20. The at least one non-transitory machine-readable storage medium of claim 19, wherein a first magnitude associated with the first PCB vibration is substantially equal to and opposite from a second magnitude associated with the second PCB vibration.
